(19) United States
(12) Patent Application Publication
(10) Pub. No.: US 2025/0167727 A1
(43) Pub. Date: May 22, 2025

(54) ELECTRO-MAGNETIC RADIATION CONCENTRATOR AND METHOD OF USING THE SAME

(71) Applicant: Leonard Steven David Johnson, Redwood Estates, CA (US)

(72) Inventor: Leonard Steven David Johnson, Redwood Estates, CA (US)

(21) Appl. No.: 18/954,474

(22) Filed: Nov. 20, 2024

Related U.S. Application Data
(60) Provisional application No. 63/601,192, filed on Nov. 20, 2023.

(51) Int. Cl. H02S 40/22; H02S 20/32

(52) U.S. Cl. CPC H02S 40/22; H02S 20/32

(57) ABSTRACT

A solar concentrator used to harness heat and electrical energy from the sun that is particularly effective for rural areas, as well as a method for using the same. The solar concentrator can be used as a stand alone device for simple energy generation, or as a just a part of a larger energy system. In either scenario the solar concentrator is a cost-efficient, and simple to implement device which makes implementation in low-income, or developing areas much easier than existing solar energy collection devices and systems.

### CROSS-REFERENCE TO RELATED APPLICATIONS

This present application claims priority to U.S. Provisional Patent Application No. 63/601,192, filed with the U.S. Patent and Trademark Office on Nov. 20, 2023 and titled “Sunlight Concentrator,” the contents of which are incorporated herein in their entirety.

### TECHNICAL FIELD

The present disclosure is generally related to solar energy devices and methods of use. Some embodiments of the present disclosure relate to solar concentrators and the method of using the same.

### BACKGROUND

The use of photovoltaic panels, referred to as “solar panels,” has become prevalent for purposes of generating energy for both residential and commercial use, while mitigating the adverse environmental impact of traditional energy sources. Solar panels are capable of converting solar electro-magnetic radiation or energy into electrical energy. This functionality can be particularly useful in environments where the solar panels are connected to and/or integrated with the load-side, or edge, of an electric grid such that the solar panels can produce electrical energy to supply the load at the edge, or when the energy demand is low at the load, supply energy back to the energy grid. However, in environments where the solar panels are separated from the electric grid, i.e., in rural locations, the electrical energy created by the solar panels at times when demand is low can be lost, which in turn, renders the use of the solar panels less efficient and desirable in those rural areas. Additionally, since solar panels are generally solid opaque objects that do not transmit electro-magnetic radiation, when used in rural agricultural areas, they can case shade on the underlying land, making it difficult or impossible to grow plants in the same areas where the solar panels are placed. These obstacles detract from the ability to use cheaper rural land for solar energy generation.

In addition to solar panels that convert electro-magnetic solar radiation to electrical energy using a photovoltaic effect, solar concentrators can also convert electro-magnetic radiation to electrical energy through indirect means (e.g., heating water to create steam to drive a turbine, focusing electro-magnetic radiation on an indirect photo-voltaic material, or other types of electro-magnetic radiation-to-electrical energy conversion as known in the art). However, like their solar panel cousins, solar concentrators, such as parabolic dish solar concentrators or linear Fresnel solar concentrators, also are generally solid, opaque objects that cast shadows on the ground and present the same problem as solar panels discussed above when used in rural areas.

### BRIEF SUMMARY OF EMBODIMENTS

The present disclosure relates to solar concentrators and methods of using the same. For example, in some embodiments, a solar concentrator may include a frame, a lens, and a panel. Components used in the solar concentrator, such as the frame, lens, and panel, may be fabricated using transparent materials. In some embodiments, the frame supports the lens above the panel and the lens is positioned to focus or concentrate electro-magnetic radiation on a target area on a surface of the panel. The concentrated electro-magnetic radiation can be used to harness either thermal or electrical energy.

In some examples, a solar concentrator may include a frame that extends vertically from a base. The solar concentrator may also include a lens mount affixed to the frame that holds a lens. The solar concentrator may include a panel that is horizontally oriented below the lens such that any electro-magnetic radiation that passes through the lens results in a concentrated beam of electro-magnetic radiation that is projected onto the panel. The solar concentrator may also include a target area that is attached to the panel such that the concentrated beam of electro-magnetic radiation can be positioned to be projected onto the center of the target area.

In embodiments, one or more of the components of the frame, lens, panel, and target area are fabricated from transparent materials, such as glass or plastic, which permit electro-magnetic radiation to pass through the components without casting a shadow, or that only partially attenuating the electro-magnetic radiation.

In embodiments, the concentrated electro-magnetic radiation heats the target area, or an object in the target area.

In embodiments, the target area includes a photovoltaic material, and which produces electrical energy from the concentrated electro-magnetic radiation.

In embodiments, the target area may be an enclosure with liquid disposed therein. The liquid may be water, such that the water converts to steam when sufficiently heated by the concentrated electro-magnetic radiation. The steam may then be used to drive a turbine to generate electricity.

In embodiments the electro-magnetic concentrator can be made to the size of a greenhouse. This would allow for the concentration of sunlight while also being able to utilize the greenhouse effect to grow plants in colder seasons, or plants that can only be grown in particular areas if they are grown in greenhouses.

### BRIEF DESCRIPTION OF THE DRAWINGS

Various embodiments are disclosed herein and described in detail with reference to the following figures. The drawings are provided for purposes of illustration only and merely depict typical or example embodiments of the disclosed technology. These drawings are provided to facilitate the reader's understanding of the disclosed technology and shall not be considered limiting of the breadth, scope, or applicability thereof. It should be noted that for clarity and ease of illustration these drawings are not necessarily made to scale.

FIG. 1 illustrates a front view of the solar concentrator.

FIG. 2 illustrates a side view of the solar concentrator.

FIG. 3 illustrates plan view of the solar concentrator.

The figures are not intended to be exhaustive or to limit the presently disclosed technology to the precise form disclosed. It should be understood that the presently disclosed technology can be practiced with modification and alteration, and that the disclosed technology be limited only by the claims and the equivalents thereof.

### DETAILED DESCRIPTION

The present disclosure provides a solar concentrator, embodiments of which can be implemented to concentrate electro-magnetic radiation for energy collection. In various embodiments, the solar concentrator may include a frame, a lens mount, a lens, a panel, and a target area. In embodiments, the components may be fabricated from a transparent material. In some embodiments, the solar concentrator may be used to concentrate electro-magnetic radiation to collect heat energy or electrical energy.

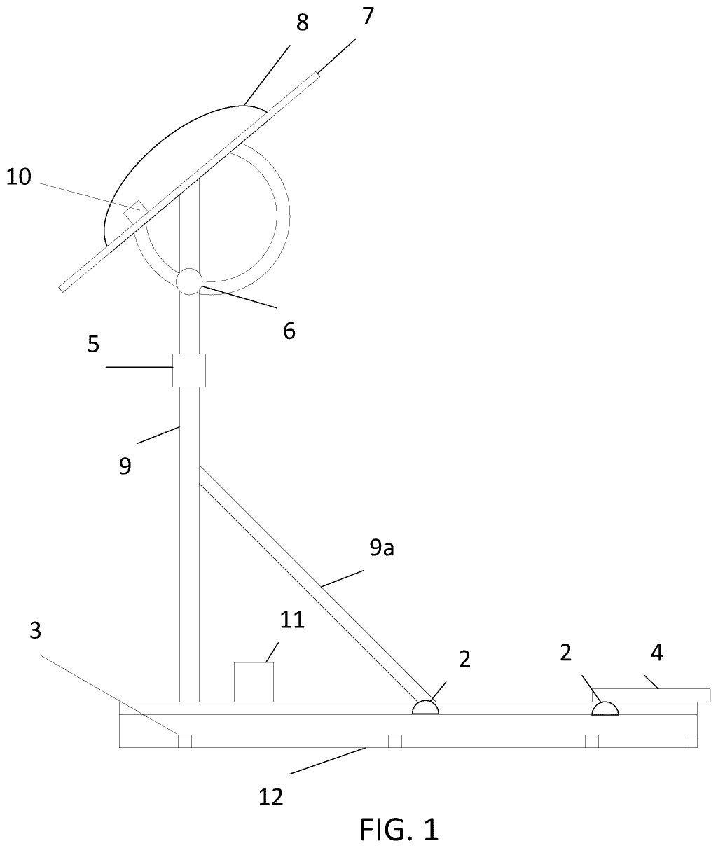

FIG. 1 illustrates a front view of an example solar concentrator, in accordance with various embodiments of the present disclosure. As illustrated in FIG. 1, frame 9 is a vertical length that extends vertical from a base 12, the length of the frame being adjusted via linear actuators 5. For example, the height of frame 9 can be raised or lowered by extending or retracting, respective to the base 12, linear actuators 5. A lens mount 7 may be affixed to an upper portion of the frame 9. In some examples, lens mount 7 is coupled to the upper portion of frame 9 using a hinge coupling 6. In some examples, hinge coupling 6 may swivel or bend, to adjust an angle of lens mount 7 relative to frame 9. Lens mount 7 may rigidly couple to and support lens 8, such that the position of lens 8 may be adjusted by raising or lowering frame 9 and/or adjusting the angle of the lens mount 7.

For example, by adjusting the height of the frame 9 via the linear actuators 5, the height of the lens 8 is changed the by the same distance. Similarly, when the angle of the lens mount 7 relative to frame 9 is adjusted, the angle of the lens 8 relative to the frame is changed by the same amount. By making these adjustments, the angle of lens 8 relative to the sun may be changed to increase the amount of electro-magnetic radiation that is collected at any given time during the day (e.g, as the relative position of the sun in the sky changes, the lens position can be adjusted in a corresponding manner).

Consistent with the above disclosure, a concentrated electro-magnetic radiation may be projected through lens 8 and focused or concentrated at the target. By adjusting the position of the lens 8, i.e., adjusting the height of the frame 9 and the angle of the lens mount 7, the resulting concentrated beam of electro-magnetic radiation can be manipulated. For example, making an adjustment to the height of the lens 8 may result in the concentrated beam of electro-magnetic radiation become less focused or more focused. Similarly, adjusting the angle of the lens 8 may also result in a less focused or more focused concentrated beam of electro-magnetic radiation. Additionally, by adjusting the tilt of the lens 8, where the concentrated beam of electro-magnetic radiation is terminated, i.e., where it hits the panel is adjusted accordingly.

The panel 1 includes a spoke 13. The spoke 13 may extend from the center of the panel 1 to a point on the edge of the panel 1. Alternatively the spoke 13 may extend from one point on the edge of the panel 1 to another point on the edge of the panel 1.

The panel 1 may further include a wheel 3 such that the panel 1 rotates atop the base 12 via the wheel. The panel 1 may be further include a target area 4 also may include a wheel 3. The target area 4 is attached to the spoke 13 of the panel 1 such that the target area is able to slide along the spoke of the panel 1.

The concentrated beam of electro-magnetic radiation from the lens 8 is directed towards the panel 1. The panel 1 may be rotated such that the concentrated beam of electro-magnetic radiation from the lens 8 and the target area 4 are linearly aligned. The target area 4 can be slid along the spoke such that the concentrated beam of electro-magnetic radiation from the lens 8 is centered on the target area 4.

The solar concentrator may include a shadow frame chaser 10, that is in turn may include of a first sight and a second sight. The first and second sights are rectangular protrusions that attached to the lens mount 7 and extend outward towards the lens 8, such that the sights represent a miniature scale version of the lens mount 7. Thus, the shadow frame chaser 10, the lens mount 7, and lens 8 are all connected such that they are all oriented in the same manner along a plane.

The first sight of the shadow frame chaser 10 and second sight of the shadow frame chaser 10 are parallel to each other and separated by a distance. As a result, when the electro-magnetic radiation shines on the shadow frame chaser 10, the resulting shadows is that of the outline of each individual sight that are offset from each other if the first sight and second sight if the first sight of the shadow frame chaser 10, second sight of the shadow frame chaser 10, and the sun are not linearly aligned. However, when the first sight of the shadow frame chaser 10, second sight of the shadow frame chaser 10, and the sun are all linearly aligned only a singular shadow of the outline of the sights is cast. By adjusting the tilt of the lens mount 7, and therefore the tilt of shadow frame chaser 10, the shadows from the first sight of the shadow frame chaser 10 and the second sight of the shadow frame chaser 10 are changed accordingly. As a result when the first sight and the second sight of the shadow frame chaser 10 only cast a singular shadow, i.e. the first sight, second sight, and sun are linearly aligned, then a used knows that the top portion of the lens mount 7 and the lower portion of the lens mount 7, as well as the top portion of the lens 8 and the lower portion of the lens 8 are linearly aligned with the sun as well.

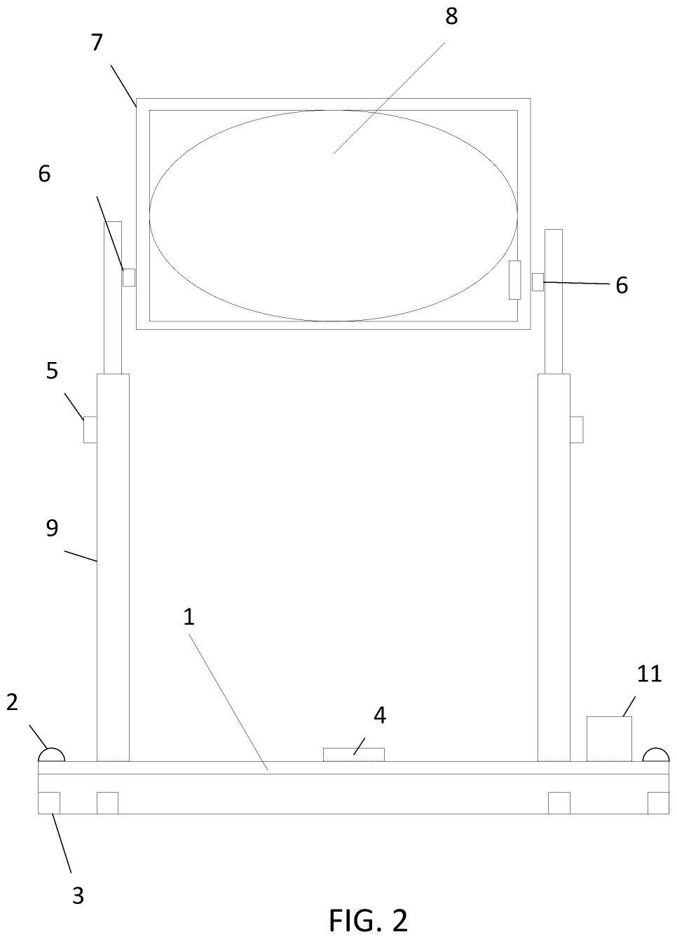

FIG. 2 illustrates a side view of an example solar concentrator, which better illustrates the tilt axis the lens mount 7, and accordingly the lens 8 and shadow frame chaser 10 can be adjusted along.

Frame supports 9a may also be used to further support and distribute the weight of the frame 9, lens mount, 7, lens 8, and shadow frame chaser 10.

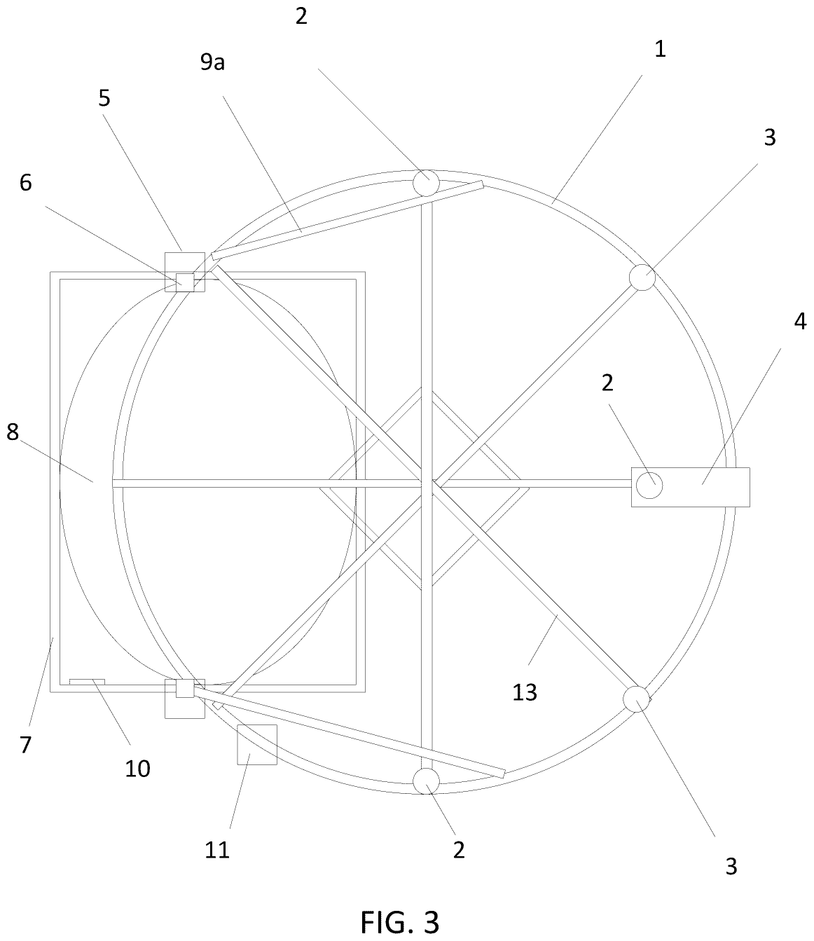

FIG. 3 illustrates a plan view of an example solar concentrator, which better illustrates the panel 1 and the target area 4.

In some embodiments, at least one of the wheels 3 that the panel 1 lies atop, may be motorized wheels 2. Thus, instead of needing an external force to rotate the panel 1 along the wheels 3, the at least one motorized wheel 2 may rotate the panel 1 itself without the need of an external force.

While FIG. 3 illustrates the panel 1 as a circular shape it should be noted that the panel 1 may be an ellipse or an arc, or any other shape that would be suitable for tracing the path of the sun.

In one embodiment of the solar concentrator, the target area 4 may be a cylindrical container that holds a thermal fluid such as water, oil, ammonia, or any other thermal fluid known to one skilled in the art.

In another embodiment of the solar concentrator, the target area is a flat surface in which in object, such as food, can be placed to be heated.

In yet another embodiment of the solar concentrator, the target area may be a photovoltaic solar panel that is capable of generating electrical energy from the electro-magnetic radiation.

The lens 8 may be made to be in the shape of one-third portion of a sphere, which reduces the size and weight of the lens 8 as compared to a fully spherical lens or a hemispherical lens. This shape also results of better thermal properties of the lens 8 while the lens 8 is concentrating electro-magnetic radiation, in that it does not become as hot as a spherical or hemispherical lens would.

In some embodiments, a photovoltaic solar panel or a battery or both are electrically coupled to the different components of the solar concentrator, such as the motorized wheels, or other systems or components not mentioned here.

The solar concentrator may also contain a logic unit that is programmed to track the position of the sun throughout the day and automatically adjust the position of the lens 8, panel 1, and/or target area 4 to maintain an optimized beam of concentrated electro-magnetic radiation throughout the day.

The solar concentrator described herein has practical applications as a standalone device, for example, but not limited to, warming objects in the target area 4 such as food or water. Additionally, the solar concentrator can be used as just a component in a larger system, such as for the heat source for creating steam power or as the electro-magnetic radiation source for generating solar photovoltaic energy.

The solar concentrator may be used as a backup source of energy in rural or undeveloped areas, or in times of emergency. Or alternatively, the solar concentrator may be connected to a larger energy system such as an electrical grid for supplemental energy generation.

While various embodiments of the disclosed technology have been described above, it should be understood that they have been presented by way of example only, and not of limitation. Likewise, the various diagrams may depict an example architectural or other configuration for the disclosed technology, which is done to aid in understanding the features and functionality that can be included in the disclosed technology. The disclosed technology is not restricted to the illustrated example architectures or configurations, but the desired features can be implemented using a variety of alternative architectures and configurations. It will be apparent to one of skill in the art how alternative functional, logical or physical partitioning and configurations can be implemented to implement the desired features of the technology disclosed herein. Additionally, with regard to flow diagrams, operational descriptions and method claims, the order in which the steps are presented herein shall not mandate that various embodiments be implemented to perform the recited functionality in the same order unless the context dictates otherwise.

Although the disclosed technology is described above in terms of various exemplary embodiments and implementations, it should be understood that the various features, aspects and functionality described in one or more of the individual embodiments are not limited in their applicability to the particular embodiment with which they are described, but instead can be applied, alone or in various combinations, to one or more of the other embodiments of the disclosed technology, whether or not such embodiments are described and whether or not such features are presented as being a part of a described embodiment. Thus, the breadth and scope of the technology disclosed herein should not be limited by any of the above-described exemplary embodiments.

Terms and phrases used in this document, and variations thereof, unless otherwise expressly stated, should be construed as open ended as opposed to limiting. As examples of the foregoing: the term “including” should be read as meaning “including, without limitation” or the like; the term “example” is used to provide exemplary instances of the item in discussion, not an exhaustive or limiting list thereof; the terms “a” or “an” should be read as meaning “at least one,” “one or more” or the like; and adjectives such as “conventional,” “traditional,” “normal,” “standard,” “known” and terms of similar meaning should not be construed as limiting the item described to a given time period or to an item available as of a given time, but instead should be read to encompass conventional, traditional, normal, or standard technologies that may be available or known now or at any time in the future. Likewise, where this document refers to technologies that would be apparent or known to one of ordinary skill in the art, such technologies encompass those apparent or known to the skilled artisan now or at any time in the future.

The presence of broadening words and phrases such as “one or more,” “at least,” “but not limited to” or other like phrases in some instances shall not be read to mean that the narrower case is intended or required in instances where such broadening phrases may be absent.

Additionally, the various embodiments set forth herein are described in terms of exemplary block diagrams, flow charts and other illustrations. As will become apparent to one of ordinary skill in the art after reading this document, the illustrated embodiments and their various alternatives can be implemented without confinement to the illustrated examples. For example, block diagrams and their accompanying description should not be construed as mandating a particular architecture or configuration.

What is claimed is:

1. A solar concentrator comprising:
a frame coupled to an actuator to adjust a height of the frame relative to a base;
a lens mount mechanically coupled to an upper portion of the frame by a hinge to enable the lens mount to rotate relative to the frame;
a lens affixed to the lens mount;
a panel, wherein the panel comprises a spoke extending from an edge of the panel to a central point of the panel;
wherein the panel is oriented horizontally and rotationally coupled to a the frame;
a target area, slidably coupled to the spoke; and
a shadow frame chaser comprised of a first optical sight and a second optical sight, wherein the first optical sight is oriented parallel to and higher than the second optical sight, wherein the first sight and second sights are rectangular protrusions that extend outward from the lens mount.

2. The solar concentrator of claim 1, wherein the frame comprises translucent material.

3. The solar concentrator of claim 1, wherein the lens is shaped to be a one-third portion of a sphere.

4. The solar concentrator of claim 1, wherein the first and second sights of the shadow frame chaser cast two offset shadows when the first sight, the second sight, and the sun are not in alignment.

5. The solar concentrator of claim 1, wherein the sights of the shadow frame chaser casts a single shadow when the first sight, the second sight, and the sun are in alignment.

6. The solar concentrator of claim 1, wherein the sphere is sixty inches in diameter.

7. The solar concentrator of claim 1, wherein the panel is an elliptical shape.

8. The solar concentrator of claim 1, wherein the panel has eight spokes.

9. The solar concentrator of claim 1, wherein the target area is a cylindrical container that can contain a thermal liquid.

10. The solar concentrator of claim 1, wherein the target area is a flat surface.

11. The solar concentrator of claim 1, wherein the target area is a photovoltaic solar panel.

12. The solar concentrator of claim 1, wherein at least one of the wheels of the target area and at least one of the wheels of the panel is a motorized wheel.

13. The solar concentrator of claim 11, further comprising a battery to power at least the motorized wheels.

14. The solar concentrator of claim 1, further comprising a logic unit that is programmed to automatically adjust the position of the lens, panel, and target area based on the position of the sun.

15. The solar concentrator of claim 1, further comprising a photovoltaic solar panel is electrically connected to the solar concentrator to provide solar electrical power to the solar concentrator.

16. A method of using a solar concentrator comprising:
viewing through a shadow frame chaser a first shadow cast from a first sight and a second shadow cast from a second sight;
aligning the first shadow cast from the first sight and the second shadow from the second sight, which results in a corresponding concentrated beam of electro-magnetic radiation, by adjusting a position of the lens,
wherein the position of the lens is adjusted by tilting a lens mount relative to a base and raising or lowering the height of at least one vertical length of a frame relative to the base;
aligning the concentrated beam of electro-magnetic radiation to be in line with a target area on a panel by rotating the panel; and
centering the concentrated beam of electro-magnetic radiation so that it is in the center of the target area by sliding the target area along a spoke of the panel it is attached to.

17. The method of using the solar concentrator of claim 14, wherein the concentrated beam of electro-magnetic radiation is used to heat a thermal liquid contained in the target area.

18. The method of using the solar concentrator of claim 14, wherein a logic unit automatically calculates how the position of the lens should be adjusted based on the path of the sun throughout the day.

19. The method of using the solar concentrator of claim 14, wherein the logic circuit automatically calculated how the panel should be rotated and where the target area should be slid along a spoke of the panel based on the position of the lens.

20. The method of using the solar concentrator of claim 14, wherein the logic circuit resets automatically resets the position of the lens at a predetermined time every day.
